(19) United States
(12) Patent Application Publication
(10) Pub. No.: US 2013/0199609 A1
(43) Pub. Date: Aug. 8, 2013

(54) Solar Cell Connector

(71) Applicant: Scuint Corporation, Austin, TX (US)

(72) Inventor: Steven B. Snidow, Austin, TX (US)

(73) Assignee: Scuint Corporation, Austin, TX (US)

(21) Appl. No.: 13/760,045

(22) Filed: Feb. 5, 2013

Related U.S. Application Data
(60) Provisional application No. 61/595,656, filed on Feb. 6, 2012.

(51) Int. Cl. H01L 31/05

(52) U.S. Cl. CPC H01L 31/0508
USPC 136/256

(57) ABSTRACT

A device to position solar cells on a vertical axis and provide structural support and act, optionally, as a means of electrical interconnect.

### CROSS-REFERENCE TO RELATED APPLICATIONS

This application claims the benefits of the filing of U.S. Provisional Patent Application Ser. No. 61/595,656 entitled, Solar Cell Connector, filed Feb. 6, 2012 and the specification thereof is incorporated herein by reference.

### STATEMENT REGARDING FEDERALLY SPONSORED RESEARCH OR DEVELOPMENT

Not Applicable.

### REFERENCE TO SEQUENCE LISTING, A TABLE, OR A COMPUTER PROGRAM LISTING COMPACT DISK APPENDIX

Not Applicable.

### TECHNICAL FIELD

The present invention is in the technical field of photovoltaic (solar) devices. More particularly, the present invention is in the technical field of solar cells. More particularly, the present invention is in the field of solar cell connection.

### BACKGROUND OF THE INVENTION

Conventional solar panels are flat with a minimum thickness and with larger width and length dimensions with the industry standard size panel approximately 3.28 feet wide and approximately 5.25 feet long. The result is a panel that is relatively thin and that is often considered more attractive on rooftops due to its relatively low height profile. The panel is typically constructed of a frame, backing, glass cover, various electrical components and a number of individual solar cells. A common size of solar cell is a six inch by six inch cell. A standard solar panel may include dozens of the six inch solar cells. Solar panels can vary in width and height but typically remain flat with a low vertical profile. All the solar cells within a solar panel are arranged on a plane such that the photovoltaic side of the cells are oriented in the same direction and abutted, or nearly abutted, to one another and forming, generally, a grid pattern.

The solar cells contained within solar panels are typically interconnected by metals strips referred to as “tabs.” Tabs are often made from aluminum and each solar cell will have a positive tab and a negative tab. The tabs are connected to each solar cell in a manner to assure the electrical current from the cell has a path. The tabs from different cells, such as adjoining cells, are then connected to each other to extend that principle and allow for more electrical current to flow such that each solar cell in a solar panel contributes to the total energy generation of the panel. The connection of the tabs between cells is normally achieved through soldering. Typically, cells can be thought of as being electrically grouped such that they are interconnected by tabs and then the groups are interconnected to other solar cell groups via a bus bar and forming, in total, the electrical infrastructure of a typical solar panel.

Not typical to common solar panel designs, and the electrical interconnection thereof, are structural elements for the support of solar cells other than the back substrate that is typically used for structural support. The below patents provide a review of some inventions that provide some form of structural support of solar cells other than use of a back substrate.

U.S. Pat. No. 7,988,320 (Brumels; Aug. 2, 2011) teaches us of a solar power light with stand. This invention indicates a vertical post, such as a tube, to which a small solar panel is affixed near the top and that is adjustable. The solar panel provides energy for a light fixture that is attached to an arm with arm attached to the vertical post and positioned just under the solar panel. The utility of this patent includes the adjustable, including angled, positioning of a small solar panel. This invention has utility as a task, or similar, light source.

U.S. Pat. No. 7,878,191 (Bender; Feb. 1, 2011) teaches us of a tension cable system to support a solar array. This invention discusses how to form a heliostat comprised of either mirrors or solar panels and situated in an array. The array is mounted onto a central post for vertical support. A primary tension rod is attached to the top of the post and in a manner as to allow for multi-axis movement. This primary tension rod extends both to the front of the heliostat as well as the back of the heliostat. Attached to this primary tension rod are a plurality of tension cables whose opposite ends are attached to a plurality of connectors and such that the tension cable extending from the center and primary tension rod on one side of the heliostat and to any one connector is offset and balanced by another cable connected to the opposite side of the same connector and opposite end of the primary tension rod. The plurality of connectors are dual-use and also serve the function of holding the mirror, or solar panel, into place and such that the whole can form an array. The utility of this patent is to provide an alternative method to erecting a heliostat and that teaches of an approach for providing structural support for solar panels.

U.S. Pat. No. 5,043,024 (Cammerer et al; Aug. 27, 1991) teaches us of a method for mounting solar cells. This invention utilizes clamps to hold a plurality of solar cells in place, including electrical interconnects, and such that the solar cells are arranged end-to-end and clamped to a substrate by a claw, or claws, on the ends. More specifically claimed in this invention is a connecting claw to be at least partially electrically conductive for carrying the electric current from solar cells. The utility of this patent is multi-fold and utilizes improvements of glass clamping technology cited in the patent. This invention uses a structural device for the additional purpose of carrying electric current with the limit of holding solar cells in a horizontal position.

U.S. Pat. No. 6,543,725 (Meurer et al; Apr. 8, 2003) teaches us of a flexible, foldable solar generator for spacecraft. This patent comprehends the need for solar panels to be in a folded position for launch, or for other needs, and to be extended for the purposes of electricity generation via the photovoltaic effect. In order to be foldable, this invention utilizes hinges. Other key attributes of this patent include the arrangement of five solar cells in a row that are electrically interconnected and with additional electrical connection at either end of the five cell set. For example, an electrical connection is located at the first and fifth solar cell. The patent further discusses how multiple five cell sets can be abutted against one another such that the opposing electrical connections are positioned over a hinge and a substrate referred to as a blanket. This patent shows utility in multiple ways including one approach to electrically interconnect adjacent solar cells to an adjustable, and structural, element (i.e., the hinge) but without utilizing the hinge as part of the electrical interconnect solution.

U.S. Pat. No. 4,604,494 (Shepard, Jr.; Aug. 5, 1986) teaches us of a photovoltaic cell array with light concentrating reflectors. The design employed by Shepard uses a reflector to concentrate light onto a solar cell that is oriented in an inverted, or near inverted, position to the reflector such that the light collecting face of the cell is pointed generally downward. The solar cell is held by a structure that effectively clamps the solar cell into fixed position above the reflector. The clamp device, and solar cell, are held above the reflector by armatures and wherein said armature can be electrically insulated or electrically conductive. This patent shows a unique approach to focusing light onto a single, planar and horizontal, solar cell surface with additional utility of having an armature structure designed as a multi-purpose device.

### SUMMARY OF THE INVENTION

The present invention is a multi-purpose device used to provide structural support for the placement of individual single-sided or double-sided solar cells in a vertical, or angled, position and such that the device may have the additional utility of acting as a electrical interconnect if not also a component of a larger structural support that may also be electrically interconnected.

The primary objective of the present invention is to provide for the angled mounting of individual, or grouped, solar cells where such angle may provide for additional electrical production through an improved photovoltaic effect and where such mounting is further enabled as an electrical interconnect.

The primary advantage of the present invention is to provide the necessary structural integrity to effect the angled mounting of solar cells within a solar panel or solar-enabled device.

An additional advantage of the present invention is to further enable the angled mounting of solar cells within a solar panel, or solar-enabled device, by including the electrical interconnection from individual solar cells to other solar cells and to the solar panel or solar-enabled device.

Other objects, advantages and novel features, and further scope of applicability of the present invention will be set forth in part in the detailed description to follow, taken in conjunction with the accompanying drawings, and in part will become apparent to those skilled in the art upon examination of the following, or may be learned by practice of the invention. The objects and advantages of the invention may be realized and attained by means of the instrumentalities and combinations particularly pointed out in the appended claims.

### BRIEF DESCRIPTION OF THE SEVERAL VIEWS OF THE DRAWINGS

FIG. 1 is a perspective view of a typical arrangement of solar cells with close-up side view of a typical electrical connection;

FIG. 2 is a perspective view of the present invention demonstrating the ability to hold solar cells at a vertical angle;

FIG. 3 is a perspective and transparent view of the present invention in greater detail;

FIG. 4 is a top view of one embodiment of the present invention wherein the present invention is used to form a small array;

FIG. 5 is comprised of FIG. 5A and FIG. 5B that, together, illustrates two electrical wiring options of the present invention as depicted in FIG. 4. FIG. 5A explains the present invention as wired in series and FIG. 5B explains the present invention as wired in parallel;

FIG. 6 is comprised of FIG. 6A and FIG. 6B that, together, depict two optional methods of constructing the presentation invention. FIG. 6A illustrates a two-piece construction of the present invention and FIG. 6B reflecting a three-piece construction of the present invention;

FIG. 7 is comprised of FIG. 7A and FIG. 7B. FIG. 7A shows another embodiment of the present invention and with electrical interconnects and with alternative method for solar cell mounting. FIG. 7B shows a plurality of the present invention, with solar cells, as described in FIG. 7A;

FIG. 8 is a four-part explanation of related embodiments of the present invention; and

FIG. 9 is a two-part explanation of related embodiments of the present invention illustrating its configurable attributes.

### DETAILED DESCRIPTION OF THE INVENTION

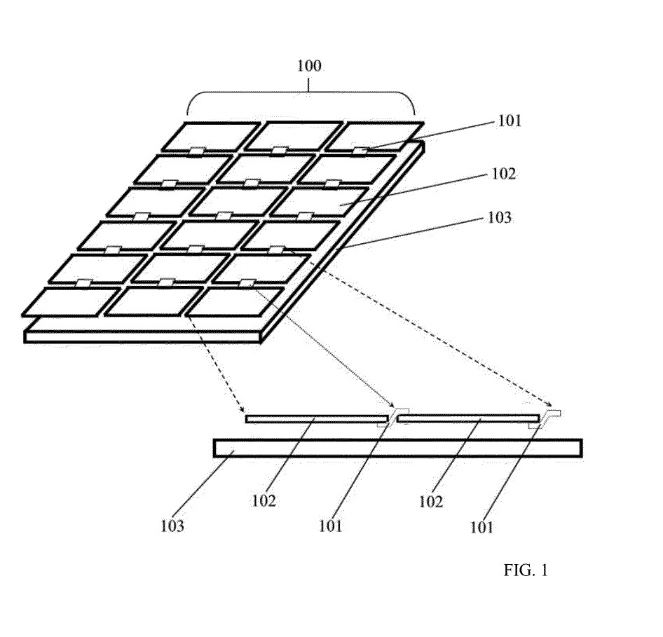

Referring to FIG. 1, a portion of a current and typically constructed solar panel 100 is shown with a backing substrate 103 on which a plurality of solar cells 102 can be electrically interconnected by connections 101. The portion of a typical solar panel 100 is shown without transparent cover, frame and other components typically found necessary for the complete construction of a typical solar panel and for the reasons of illustration only. FIG. 1 is shown instead with an additional side view showing how individual solar cells 102 are comprised to have negative and positive sides that are interconnected with “S” shaped connections 101 and with solar cells 102 with connections 101 placed above a backing substrate 103 that is required for support of the solar cells 102 that are typically laid flat on substrate 103. It should be understood that connections 101 may be understood to be “tabs” used in typical solar panel construction.

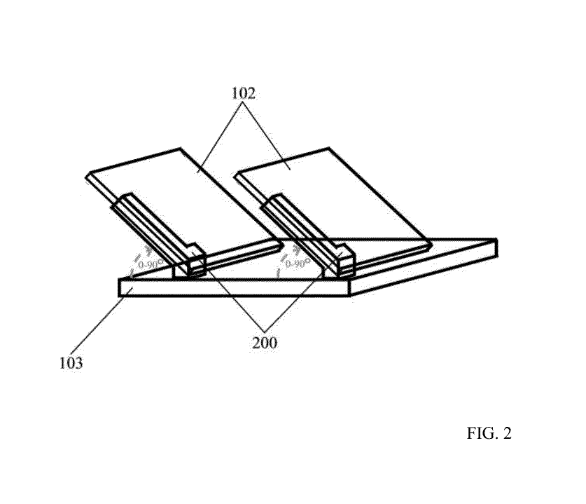

Referring now to FIG. 2 that represents the first illustration of the present invention. Solar cells 102 are now depicted to be placed onto a substrate 103 at an angle that may be any angle from 0-degrees (flat) to 90-degrees (vertical). The solar cells are now able to be placed at such degree by means of the present invention 200 that acts minimally as a support structure for the solar cell 102. As shown in subsequent figures, solar cell support 200 can also be used as an electrical interconnect to the solar cells 102. It should further be understood that for this figure and subsequent figures, solar cells 102 are meant to be defined as either a single-sided solar cell or a double-sided solar cell (or solar cell construction resulting in two active, and opposite, sides). It should further be understood that with solar cell support 200 a back substrate 103 may be no longer need to be a single, monolithic piece, such as a sheet of metal.

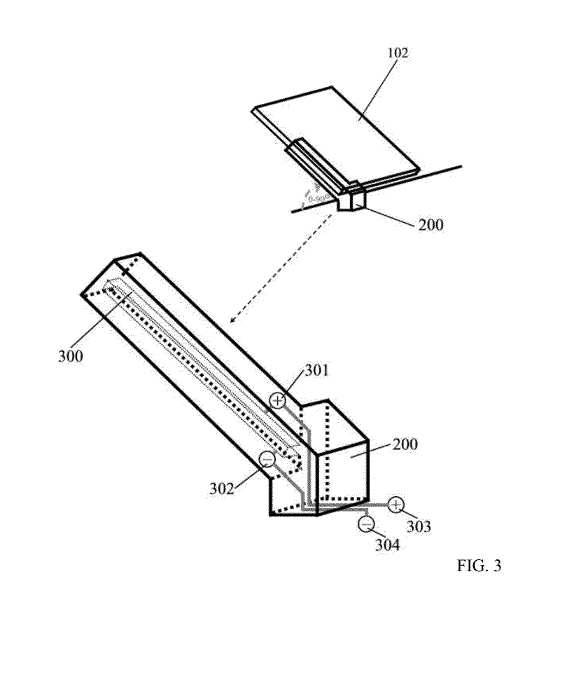

Referring now to FIG. 3, solar cell support 200, as shown in FIG. 2 securing and supporting solar cell 102, is now enlarged and shown in a transparent and perspective view to illustrate an embodiment of the present invention. Solar cell support 200 is shown to be comprised of a solar cell physical connection 300, positive solar cell electrical connect 301, negative solar cell electrical connect 302, positive electrical connect 303 and negative electrical connect 304 and wherein electrical connections 301 and 302 are contemplated to connect directly to a solar cell and electrical connections 303 and 304 are to connect to another solar cell(s) or a load. For the purposes of illustration, solar cell support 200 is shown as a one-piece device but as other figures will demonstrate, may be fabricated from multiple parts. Additionally, it should be understood that solar cell support 200 may be constructed with, or without, electrical interconnects.

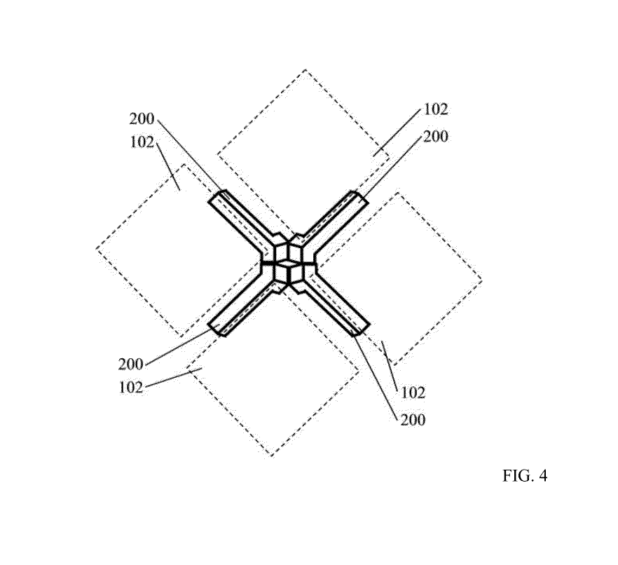

Referring now to FIG. 4 that is a top view of four solar cell supports 200 arranged with solar cells 102 and in such a way as to provide for one method of electrical interconnection to each solar cell support 200 through physical attachment to one another or close proximity to one another reducing the need for additional wiring to make such interconnection. It should be further understood that a plurality of solar cell supports 200 may be electrically interconnected directly to one another or in combination of connection to an electrically interconnected substrate such as a printed circuit board.

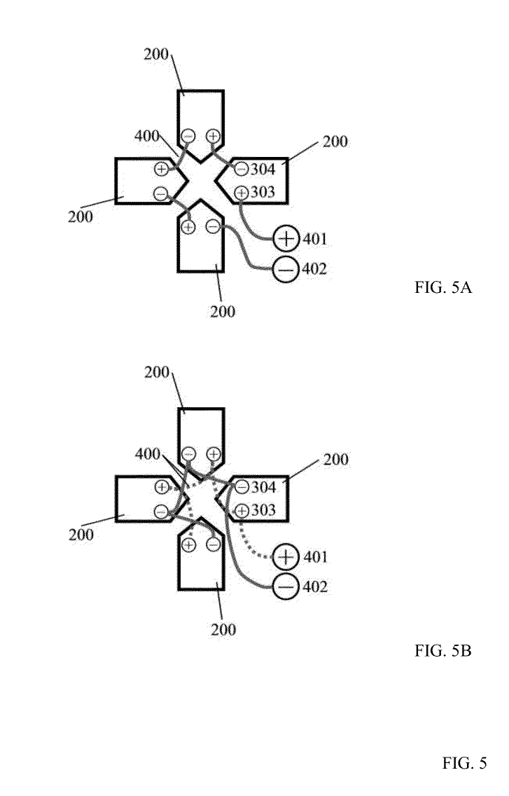

Referring now to FIG. 5 that is comprised of FIG. 5A and FIG. 5B that both represent the solar cell support 200 arrangement from FIG. 4 in simplified form and with alternative electrical interconnection. More specifically, referring now to FIG. 5A that shows the solar cell supports 200, as depicted in FIG. 4, electrically interconnected in series with each solar cell support 200 understood to have solar cell electrical interconnections 301 and 302 (not shown), positive electrical connect 303 and negative electrical connect 304 and with each solar cell support 200 interconnected to the next solar cell support 200 by electrical interconnect 400. At the terminal ends of the arrangement, the solar cell supports 200 are further connected to another device, or load, being represented by electrical connections 401 (positive) and 402 (negative). FIG. 5B depicts the same elements as FIG. 5A but with electrical interconnection in parallel resulting in additional electrical interconnections 400 between solar cell supports 200 and resulting in a terminal ending to electrical connections 401 (positive) and 402 (negative).

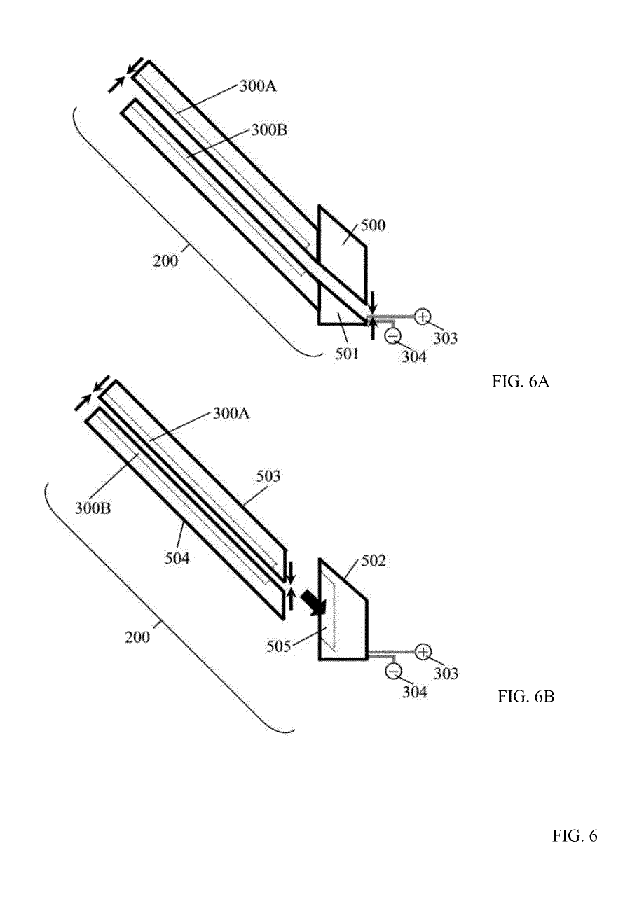

Referring now to FIG. 6 that is comprised of FIG. 6A and FIG. 6B with each figure representing an alternative approach to constructing the solar cell support 200. More specifically, referring now to FIG. 6A that shows one approach of constructing a solar cell support 200 from two primary components 500 and 501 that are fitted together and that may be secured together through various means such as adhesive or fasteners. For this depiction, solar cell physical connection to solar cell support 200 is made manifest by a slot cut into upper component 500 and lower component 501. The slot is understood to be the solar cell connection 300 described in FIG. 3 and that is now comprised of part 300A within upper component 500 and 300B within lower component 501 and such that when the upper and lower components 500 and 501 are fitted together 300A and 300B create solar cell connection 300. It should further be understood the solar cell support 200 may, or may not, have electrical interconnections. For the purposes of illustration, solar cell support 200 is shown in FIG. 6A with positive electrical connect 303 and negative electrical connect 304. Positive solar cell electrical connect 301, negative solar cell electrical connect 302 depicted in FIG. 3 are not shown, for purposes of illustration, in FIG. 6A.

Referring now to FIG. 6B that shows another approach of constructing a solar cell support 200 from three primary components 502, 503 and 504 that are fitted together and that may be secured together through various means such as adhesive or fasteners. For this depiction, solar cell physical connection to solar cell support 200 is made manifest by a slot cut into upper component 503 and lower component 504. The slot is understood to be the solar cell connection 300 described in FIG. 3 and that is now comprised of part 300A within upper component 503 and 300B within lower component 504 and such that with the upper and lower components are fitted together 300A and 300B create solar cell connection 300. It should further be understood the solar cell support 200 may, or may not, have electrical interconnections. For the purposes of illustration, solar cell support 200 is shown in FIG. 6B with positive electrical connect 303 and negative electrical connect 304. Positive solar cell electrical connect 301, negative solar cell electrical connect 302 depicted in FIG. 3 are not shown, for purposes of illustration, in FIG. 6B. It should be further understood that components 502, 503 and 504 can be interconnected and fastened together by use of recess 505 that would allow components 503 and 504, once fitted together, to be held by component 502 through compression if not also with the aid of adhesive or fasteners.

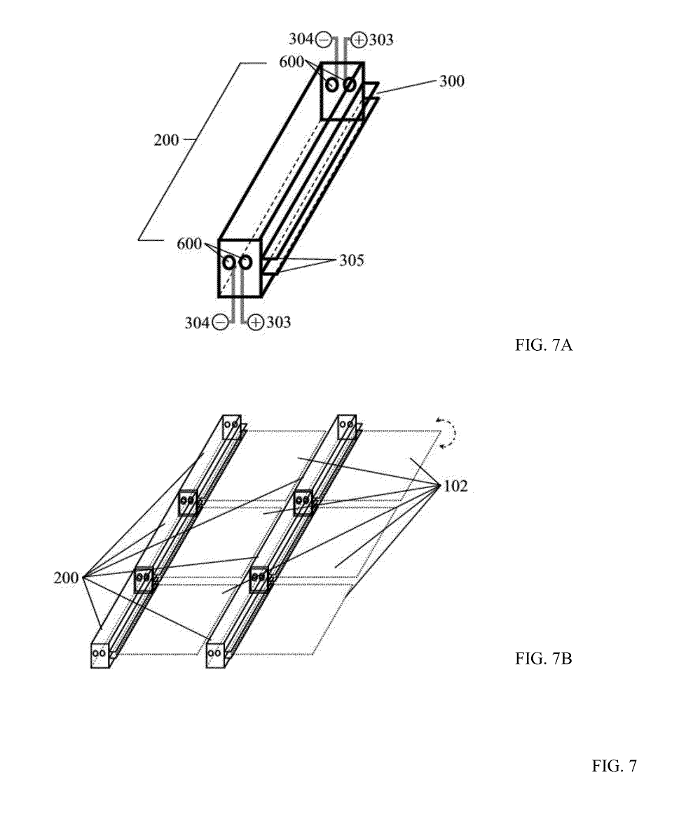

Referring now to FIG. 7A that shows another embodiment of the present invention reflecting a more detailed view of an alternative design of solar cell support 200. As depicted in FIG. 3, in FIG. 7A solar cell support 200 is shown to be constructed as a one-piece device but should be understood that it may be constructed from two, or more, components as depicted in FIG. 6A and FIG. 6B. As depicted in FIG. 7A, solar cell support 200 utilizes an alternative approach to solar cell physical connection 300 by utilizing exterior flanges 305 instead of an internal slot. Solar cell support 200 is also shown with integrated structural/electrical interconnections 600. Structural/electrical interconnections 600 are show to be at each end of solar cell support 200 and should be understood to act as a physical method to connect two, or more, solar cell supports together, such as a male-to-female connection, and may also act as an electrical interconnection. For the purposes of illustration, structural/electrical interconnections 600 are shown in FIG. 7A with the dual purpose of structural and electrical connection with positive electrical connect 303 and negative electrical connect 304 at each end. Positive solar cell electrical connect 301, negative solar cell electrical connect 302 depicted in FIG. 3 are not shown, for purposes of illustration, in FIG. 7A.

Referring now to FIG. 7B that demonstrates the principle explained and demonstrated for FIG. 7A that is, more specifically, that solar cell supports 200 can by physically and electrically interconnected and such that any number of solar cell supports 200 with solar cells 102 may be connected as may be required by end user needs. That is to be understood, the use of solar cell support 200 may be designed for multiple physical and/or electrical connections and such that each individual solar cell support 200 can be connected to other solar cell supports 200 and limited only by the available connections and overall structural integrity of the resulting array. In FIG. 7B, a simple, end-on-end connection is depicted with six solar cell supports 200 connected in two rows and with each bearing a solar cell 102.

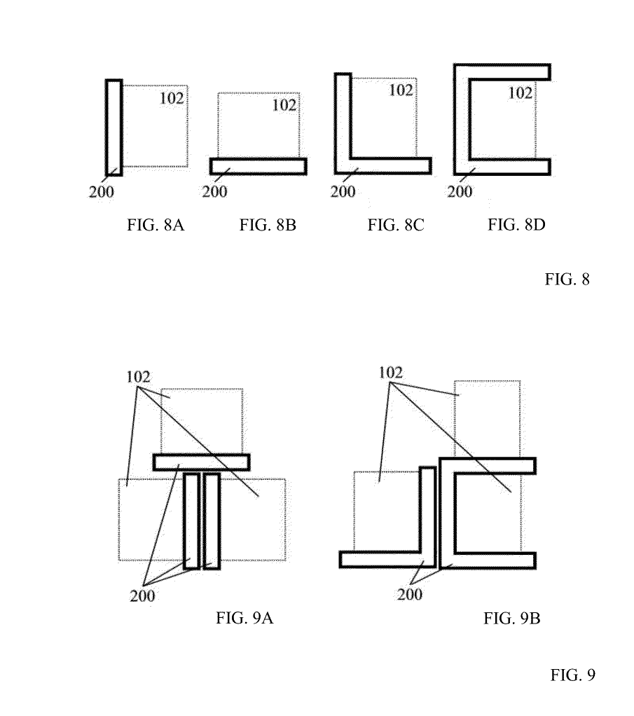

Referring now to FIG. 8 that is comprised of FIG. 8A, FIG. 8B, FIG. 8C and FIG. 8D that, together, represent the expanded utility of solar cell support 200 by explaining four alternative designs of the device. Referring now to FIG. 8A, a vertical solar cell support 200 is depicted holding a solar cell 102 and resembles the design explained in FIG. 7A and FIG. 7B. Referring now to FIG. 8B, solar cell support 200 is depicted as a horizontal support also holding a solar cell 102. Referring now to FIG. 8C, an alternative design for solar cell support 200 is now formed in an “L” shape to provide support to the vertical and horizontal axis of solar cell 102. Referring now to FIG. 8D, a solar cell support 200 is depicted in a “C” configuration and holding solar cell 102. For each design represented in FIG. 8A-8D, it should be further understood that each manifestation of solar cell support 200 may be constructed of one, or more, components and that as a whole solar cell support 200 will minimally be a structural support for solar cell 102 if not also to serve an electrical interconnect for solar cell 102.

Referring now to FIG. 9, FIG. 9 is comprised of FIG. 9A and FIG. 9B that depicts two alternative arrangements of solar cell support 200. Referring now to FIG. 9A, FIG. 9A depicts the use of three solar cell supports 200 with two of a vertical design connected to one of a horizontal design and each bearing one solar cell 102 each. Referring now to FIG. 9B, the use of two solar cell supports 200, one as an “L” design and one as a “C” design, are used in conjunction with one another and each bearing at least one solar cell 102.

The advantages of the present invention include, without limitation, the ability to provide for improved electricity generation through the alternative mounting photovoltaic cells at an angle when compared to a flat (horizontal) substrate.

In broad embodiment, the present invention is an improvement for the mounting of individual, or grouped, photovoltaic cells within a solar panel or solar-enabled device.

### DESCRIPTION OF THE PREFERRED EMBODIMENTS

### Best Modes for Carrying Out the Invention

The present invention may be used as a device to improve the performance of a traditionally designed and built flat solar panels by providing for an alternative method of mounting and electrically interconnecting solar cells and such that the solar cells may be exposed to additional light through an angled (vertical) mount.

As a preferred embodiment, the present invention is as a combined structural support constructed of a rigid material housing electrical wires and electrical interconnections on the surface of the structural support that, together, are one unit that may hold one, or more, single-sided or double-sided, solar cells and such that one end of the electrical interconnections provide electrical contact to the solar cells and the other end of the electrical interconnections provide electrical contact to other solar cells or directly to the solar panel or solar panel equivalent.

The present invention may be utilized as a substitute to and improvement over the use of solar cell tabs as electrical interconnects, solar panel flat back substrates or both solar cell tabs and solar panel flat back substrates that, together, act to structurally support and electrically interconnect a plurality of solar cells.

### INDUSTRIAL APPLICABILITY

The invention is further illustrated by the following non-limiting examples.

### Example 1

The present invention may act as a structural support for a plurality of solar cells. For example, a plurality of single-sided, conventional, silicon-based solar cells, that measure six inches by six inches, are individually mounted to a frame by means of the present invention. The present invention is an “L” shaped device that may clamp the individual solar cells on two edges and where the bottom of the “L” is connected to the frame. The “L” shaped device contains electrical connection points for the positive and negative leads of the solar cell and contains internal wiring to provide for the positive and negative electrical connections at the bottom of the “L” and that physically and electrically interconnect to the mounting frame. The mounting frame contains additional wiring enabling successive “L” shaped devices, each holding a solar cell, in a single row to be electrically connected in series and then for multiple rows of mounted solar cells to be wired in parallel. All of the solar cells are mounted at an approximate 45-degree angle and face in the same direction and such that the whole may be mounted onto a flat surface while gaining additional sunlight due to the angle of the “L” mounted solar cells.

### Example 2

The present invention may act as a structural support for a plurality of solar cells where pairs of single-sided solar cells are mounted onto a single inverted “T” shaped device. The “T” shaped embodiment of the present invention provides for lateral support for both solar cells across the bottom of the inverted “T” and for vertical support along the vertical leg of the “T”. The “T” contains the positive and negative electrical connections to connect to each solar cell. The internal wiring of the present invention provides for the two solar cells to be wired in series within the “T” shape. The inverted “T” shape is then mounted onto a swivel and where the swivel contains further electrical connections to complete the electrical interconnection of solar cells through the present invention and where the solar cell pairing is electrically interconnected to similar solar cell pairs and where all pairs are mounted on swivels with the swivels actuated by a central control and motor so that the plurality of solar cell pairs may be adjusted for position to a common light source. Each “T” shape solar cell pair is mounted so that the solar cells are at an approximate 45-degree angle.

The preceding examples can be repeated with similar success by substituting the generically or specifically described parameters and/or operating conditions of this invention for those used in the preceding examples.

While the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above described embodiment, method, and examples, but by all embodiments and methods within the scope and spirit of the invention as claimed.

I claim:

1. A rigid photovoltaic cell structural support device comprised of at least one formed component and that is formed to secure and structurally support at least one photovoltaic cell and where photovoltaic cell(s) are positioned at an angle greater than zero degrees as measured from a horizontal axis;

2. A rigid photovoltaic cell structural support device comprised of at least one formed component and that is formed to secure and structurally support at least one photovoltaic cell and where photovoltaic cell(s) are positioned at an angle greater than zero degrees as measured from a horizontal axis and where rigid photovoltaic cell structural support device includes electrical wiring and connection that provides an electrical connection from at least one solar cell secured by the rigid photovoltaic cell structural support device to at least one other solar panel component;

3. A rigid photovoltaic cell structural support device comprised of at least one formed component and that is formed to secure and structurally support at least one photovoltaic cell and where photovoltaic cell(s) are positioned at an angle greater than zero degrees as measured from a horizontal axis and where rigid photovoltaic cell structural support device includes electrical wiring and connection that provides an electrical connection from at least one solar cell secured by the rigid photovoltaic cell structural support device to at least one other solar panel component and where the non-solar cell electrical interconnections of rigid photovoltaic cell structural support device are formed into connectable male and female contacts.
